(19) United States
(12) Patent Application Publication
(10) Pub. No.: US 2021/0175425 A1
(43) Pub. Date: Jun. 10, 2021

(54) METHOD FOR FORMING PEROVSKITE LAYER AND FORMING STRUCTURE COMPRISING PEROVSKITE LAYER

(71) Applicant: Industrial Technology Research Institute, Hsinchu (TW)

(72) Inventors: Shih-Hsiung Wu, Tainan City (TW); Yung-Liang Tung, Hsinchu County (TW); Kuo-Wei Huang, Yunlin County (TW); Pei-Ting Chiu, Kaohsiung City (TW); Hung-Ru Hsu, Changhua County (TW); Jia-Ming Lin, Kaohsiung City (TW)

(73) Assignee: Industrial Technology Research Institute, Hsinchu (TW)

(21) Appl. No.: 16/708,446

(22) Filed: Dec. 10, 2019

(30) Foreign Application Priority Data
Dec. 6, 2019 (TW) 108144603

(51) Int. Cl. H01L 51/00; H01L 51/42

(52) U.S. Cl. CPC H01L 51/0027; H01L 51/0003; H01L 2251/10; H01L 2251/30; H01L 51/4213

(57) ABSTRACT

Provided are a method for forming a perovskite layer and a method for forming a structure comprising a perovskite layer. The method for forming a perovskite layer includes the following steps: coating a perovskite precursor material on a substrate; and performing a heating treatment to the substrate; and irradiating the perovskite precursor material with infrared light.

### CROSS-REFERENCE TO RELATED APPLICATION

This application claims the priority benefit of Taiwan application serial no. 108144603, filed on Dec. 6, 2019. The entirety of the above-mentioned patent application is hereby incorporated by reference herein and made a part of this specification.

### BACKGROUND

### Technical Field

The disclosure relates to a method for forming a perovskite layer and a method for forming a structure including a perovskite layer.

### Related Art

Because perovskite materials are excellent optoelectronic materials, they are widely used in solar cells. Generally, in the process of forming a perovskite layer on a substrate, first, a perovskite precursor material is coated on the substrate, and then the substrate is heated by a heating plate disposed below the substrate to volatilize the solvent in the perovskite precursor material and cause reaction in the perovskite precursor to form the perovskite layer.

However, in large-area mass production of perovskite materials, supplying energy from below the substrate by using a heating plate may cause an issue of a disuniform heating temperature, which results in poor quality of the formed perovskite layer. In addition, in the manufacturing process of a solar cell, when a hole transport layer (HTL) is formed on the perovskite layer, because the sputtering process causes damage to the perovskite layer, it is not easy to use an inorganic layer as the hole transport layer on the perovskite layer.

### SUMMARY

A method for forming a perovskite layer according to the disclosure includes the following steps. A perovskite precursor material is coated on a substrate. A heating treatment is performed on the substrate. An infrared light irradiation is performed on the perovskite precursor material.

A method for forming a structure including a perovskite layer according to the disclosure includes the following steps. A perovskite layer is formed on a substrate. A first ultraviolet light irradiation is performed on the perovskite layer to form a protective layer on the perovskite layer. A material of the protective layer includes a halide BX₂, where B is Pb, Sn, or Ge, and X is Cl, Br, or I.

To make the above features and advantages of the disclosure more comprehensible, embodiments accompanied with drawings are described in detail as follows.

### BRIEF DESCRIPTION OF THE DRAWINGS

FIG. 1 is a flowchart showing a method for forming a perovskite layer according to a first embodiment of the disclosure.

FIG. 2 is a flowchart showing a method for forming a perovskite layer according to a second embodiment of the disclosure.

FIG. 3 is a flowchart showing a method for forming a perovskite layer according to a third embodiment of the disclosure.

FIG. 4 is a flowchart showing a method for forming a structure including a perovskite layer according to an embodiment of the disclosure.

FIG. 5A to FIG. 5C are schematic cross-sectional views showing a method for forming a structure including a perovskite layer according to an embodiment of the disclosure.

### DESCRIPTION OF THE EMBODIMENTS

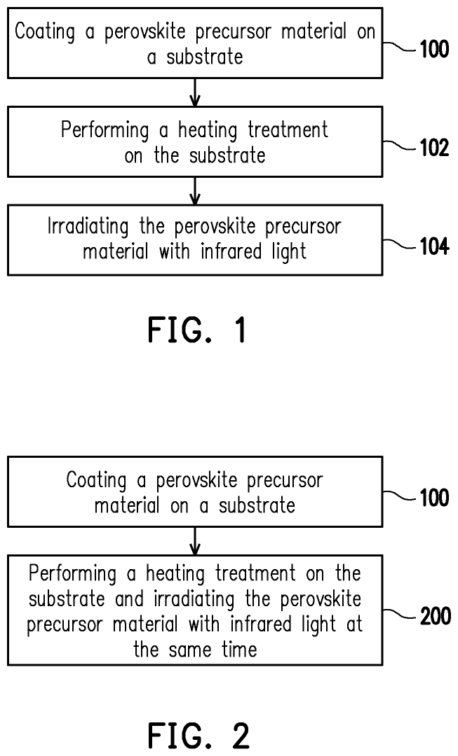

FIG. 1 is a flowchart showing a method for forming a perovskite layer according to a first embodiment of the disclosure. Referring to FIG. 1, in step 100, a perovskite precursor material is coated on a substrate. In an embodiment, the perovskite precursor material includes a perovskite material ABX₃ and an organic solvent, where the perovskite material ABX₃ is, for example, an ABX₃-type organic-inorganic composite perovskite material, A is an organic ammonium material (e.g., CH₃NH₃, CH₃CH₂NH₃, NH₂CH═NH₂, etc.), B is a metal material (e.g., Pb, Sn, Ge, etc.), X is a halogen (e.g., Cl, Br, or I), and the organic solvent is used to dissolve the perovskite material. The organic solvent may be, for example, γ-butyrolactone (GBL), dimethyl sulfoxide (DMSO), dimethylformamide (DMF), or a mixed solvent thereof. In other embodiments, reference may be made to J. Mater. Chem. A, 2015, 3, 8926-8942 and Chem. Soc. Rev., 2019, 48, 2011-2038 for other perovskite precursor materials, and the disclosure is not limited thereto.

In the embodiment, the substrate is, for example, a substrate in a solar cell, and the substrate may be a transparent or non-transparent rigid or flexible substrate, but the disclosure is not limited thereto. In other embodiments, the substrate may be any suitable substrates. In addition, in the embodiment, the method of coating the perovskite precursor material is, for example, a blade coating method, slot-die coating, spray coating, etc. When the substrate is a large-sized substrate, by coating the perovskite precursor material through the blade coating method, the perovskite precursor material can be uniformly distributed on the substrate, which is favorable for the growth of the perovskite layer. In addition, through the blade coating method, the surface of the thin film can be smoother, and by adjusting the blade gap, the thickness of the thin film can be better controlled. Moreover, the blade coating method has the advantages of a simple process and low equipment costs. However, in the disclosure, the method for coating the perovskite precursor material is not limited to the blade coating method, and the various methods described above may also be used to coat the perovskite precursor material.

Next, in step 102, after the perovskite precursor material is coated, a heating treatment is performed on the substrate to volatilize the solvent in the perovskite precursor material to generate crystal nuclei, and to cause reaction in the perovskite precursor to gradually grow a dense perovskite thin film. In the embodiment, the substrate is heated from under the substrate by using a heating plate, for example, and the temperature of the heating treatment is between 60° C. and 150° C., for example. When the heating temperature is lower than 60° C., the main solvent cannot be volatilized. When the heating temperature is higher than 150° C., perovskite decomposition may occur. The duration of the heating treatment is, for example, between 30 minutes and 1 hour.

Then, in step 104, after the heating treatment of the substrate is stopped, the perovskite precursor material is irradiated with infrared light to accelerate the volatilization of the solvent in the perovskite precursor material and form a perovskite layer having large grains (300 nm to 500 nm). In addition, when the infrared light irradiation is performed, the element (ABX₃) in the perovskite precursor material can be uniformly diffused, so a perovskite layer with improved quality can be formed. Moreover, through the above method, a 2D/3D hybrid structure perovskite layer can be formed. In the embodiment, the infrared light irradiation uses infrared light having a wavelength of 700 nm to 1400 nm, for example, and the duration of the infrared light irradiation is between 20 seconds and 30 minutes, for example. The 2D/3D hybrid structure perovskite layer cannot be formed if the duration is less than 20 seconds, and perovskite crystal decomposition may occur if the duration is more than 30 minutes.

The perovskite layer of a comparative example (without infrared light irradiation after heating at 100° C. for 1 hour to form perovskite) and the perovskite layer of the embodiment (irradiated with infrared light for 30 minutes after heating at 100° C. for 1 hour to form perovskite) were subsequently sequentially deposited with spiro-OMeTAD and Au electrodes to form solar cells. Then, a light irradiation test was performed under light irradiation conditions of AM1.5, 1000 W/m², and 25° C. After the test, in terms of efficiency, the efficiency (12.4%) of the solar cell having the perovskite layer of the embodiment was significantly higher than the efficiency (10.0%) of the solar cell having the perovskite layer of the comparative example. In addition, in terms of the short-circuit current, the short-circuit current (16.0 mA/cm²) of the solar cell having the perovskite layer of the embodiment was significantly higher than the short-circuit current (14.0 mA/cm²) of the solar cell having the perovskite layer of the comparative example.

FIG. 2 is a flowchart showing a method for forming a perovskite layer according to a second embodiment of the disclosure. In the embodiment, the same steps as in the first embodiment will not be described again.

Referring to FIG. 2, as in the first embodiment, in step 100, a perovskite precursor material is coated on a substrate. Next, in step 200, a heating treatment is performed on the substrate and the perovskite precursor material is irradiated with infrared light at the same time. In the embodiment, the substrate is heated from under the substrate by using a heating plate, for example. The temperature of the heating treatment is, for example, between 60° C. and 150° C., and the duration of the heating treatment is, for example, between 30 minutes and 1 hour. In addition, the infrared light irradiation uses infrared light having a wavelength of 700 nm to 1400 nm, for example, and the duration of the infrared light irradiation is between 20 seconds and 30 minutes, for example. Since the duration of the infrared light irradiation is not longer than the duration of the heating treatment, the infrared light irradiation may be performed within the time period of the heating treatment, or the start time may fall within the time period of the heating treatment, and the two are simultaneously performed for at least a period of time.

In an embodiment, the heating treatment and the infrared light irradiation may be started at the same time, or may be ended at the same time, but the disclosure is not limited thereto. In other embodiments, the heating treatment and the infrared light irradiation may be started at different times, and the infrared light irradiation may be ended before, at the same time as, or after the heating treatment. In the embodiment, since the heating treatment and the infrared light irradiation are performed simultaneously, the volatilization of the solvent in the perovskite precursor material can be accelerated to form a perovskite layer having large grains (300 nm to 1.5 μm).

The perovskite layer of a comparative example (without infrared light irradiation during heating at 100° C. for 1 hour to form perovskite) and the perovskite layer of the embodiment (starting the infrared light irradiation for 10 minutes at the same time during heating at 100° C. for 1 hour to form perovskite) were subsequently sequentially deposited with spiro-OMeTAD and Au electrodes to form solar cells. Then, a light irradiation test was performed under light irradiation conditions of AM1.5, 1000 W/m², and 25° C. After the test, in terms of efficiency, the efficiency (16.5%) of the solar cell having the perovskite layer of the embodiment is significantly higher than the efficiency (15.3%) of the solar cell having the perovskite layer of the comparative example. In addition, in terms of the fill factor, the fill factor (0.74) of the solar cell having the perovskite layer of the embodiment is significantly higher than the fill factor (0.68) of the solar cell having the perovskite layer of the comparative example.

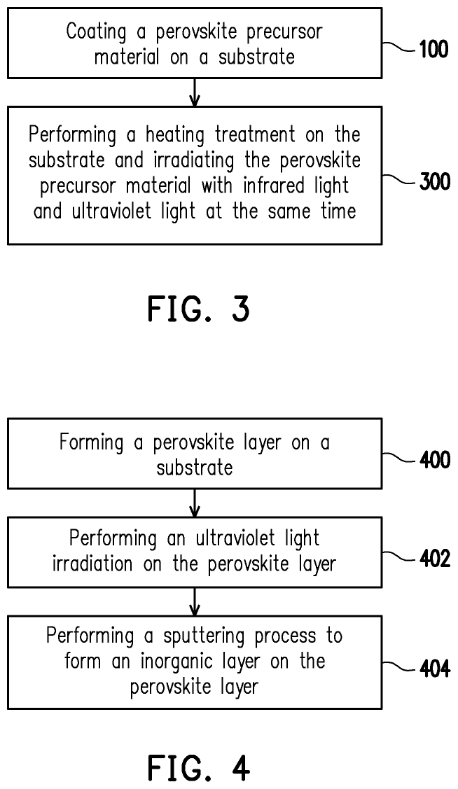

FIG. 3 is a flowchart showing a method for forming a perovskite layer according to a third embodiment of the disclosure. In the embodiment, the same steps as in the first embodiment will not be described again.

Referring to FIG. 3, as in the first embodiment, in step 100, a perovskite precursor material is coated on a substrate. Next, in step 300, a heating treatment is performed on the substrate and the perovskite precursor material is irradiated with infrared light and ultraviolet light at the same time. In the embodiment, the substrate is heated from under the substrate by using a heating plate, for example. The temperature of the heating treatment is, for example, between 60° C. and 150° C., and the duration of the heating treatment is, for example, between 30 minutes and 1 hour. In addition, the infrared light irradiation uses infrared light having a wavelength of 700 nm to 1400 nm, for example, and the duration of the infrared light irradiation is between 20 seconds and 30 minutes, for example. Moreover, the ultraviolet light irradiation uses ultraviolet light having a wavelength of 320 nm to 400 nm, and the duration of the ultraviolet light irradiation is not more than 600 seconds. If the duration is more than 600 seconds, perovskite crystal decomposition may occur.

In an embodiment, the heating treatment, the infrared light irradiation, and the ultraviolet light irradiation are started at the same time, or may be ended at the same time, but the disclosure is not limited thereto. In other embodiments, the heating treatment, the infrared light irradiation, and the ultraviolet light irradiation may be started at different times and the infrared light irradiation may be ended first. Alternatively, the heating treatment and the infrared light irradiation may be started at the same time, and the end time of the infrared light irradiation is not later than the end time of the ultraviolet light irradiation. In other words, there are further possibilities as long as the ultraviolet light irradiation is performed within the time period of the heating treatment and the end time of the infrared light irradiation is not later than the end time of the ultraviolet light irradiation. Accordingly, the volatilization of the solvent in the perovskite precursor material can be accelerated to form a perovskite layer having large grains (300 nm to 1 μm). In addition, since the perovskite precursor material is irradiated with ultraviolet light, the bonding between the molecules in the perovskite precursor material can be activated to recrystallize the grain boundary, and thus the hysteretic response can be effectively reduced.

The perovskite layer of a comparative example (without infrared light irradiation and ultraviolet light irradiation during heating at 100° C. for 1 hour to form perovskite) and the perovskite layer of the embodiment (starting the infrared light irradiation for 10 minutes and the ultraviolet light irradiation for 10 minutes at the same time during heating at 100° C. for 1 hour to form perovskite) were subsequently sequentially deposited with spiro-OMeTAD and Au electrodes to form solar cells. Then, a light irradiation test was performed under light irradiation conditions of AM1.5, 1000 W/m², and 25° C. After the test, in terms of efficiency, the efficiency (14.6%) of the solar cell having the perovskite layer of the embodiment is significantly higher than the efficiency (13.6%) of the solar cell having the perovskite layer of the comparative example. In addition, in terms of the improved hysteretic response, the hysteresis index (2.5 mA/cm²) of the solar cell having the perovskite layer of the embodiment is significantly lower than the hysteresis index (6.5 mA/cm²) of the solar cell having the perovskite layer of the comparative example.

In addition, when the perovskite layer of the disclosure is applied to a solar cell, various film layers (e.g., a protective layer, a hole transport layer, etc.) are formed on the perovskite layer to form a stacked structure including the perovskite layer, which will be described below.

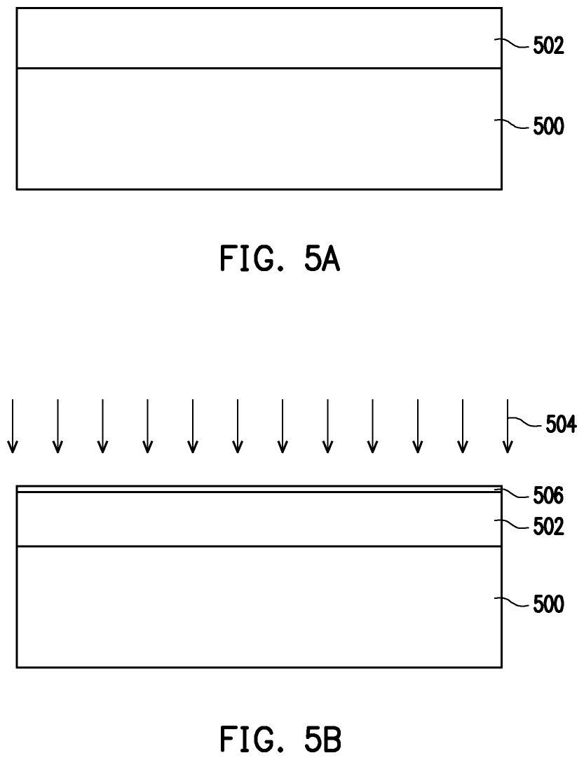

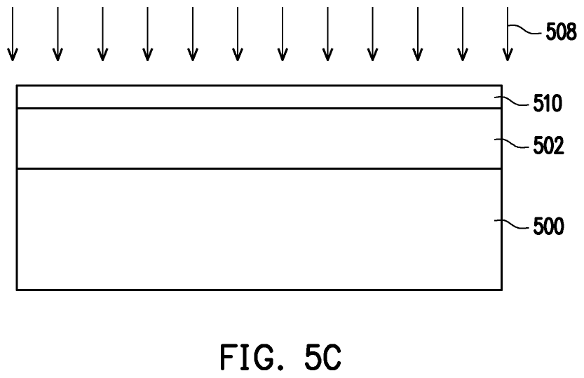

FIG. 4 is a flowchart showing a method for forming a structure including a perovskite layer according to an embodiment of the disclosure. FIG. 5A to FIG. 5C are schematic cross-sectional views showing a method for forming a structure including a perovskite layer according to an embodiment of the disclosure. Referring to FIG. 4 and FIG. 5A at the same time, in step 400, a perovskite layer 502 is formed on a substrate 500. In the embodiment, the method for forming the perovskite layer 502 is not specifically limited. For example, the perovskite layer 502 may be formed with reference to the first embodiment, the second embodiment, the third embodiment above, or various existing methods, such as the various methods as described on pages 417 to 446 of Nanomaterials for Solar Cell Applications 2019.

Referring to FIG. 4 and FIG. 5B at the same time, in step 402, after the perovskite layer 502 is formed, an ultraviolet light irradiation 504 is performed on the perovskite layer 502 to form a thin film 506 at the surface (the portion exposed to the ultraviolet light irradiation 504 and inward) of the perovskite layer 502. The ultraviolet light irradiation 504 is different from the ultraviolet light irradiation used to form the perovskite layer in the third embodiment. In the embodiment, the ultraviolet light irradiation 504 uses ultraviolet light having a wavelength of 320 nm to 400 nm, and the duration of the ultraviolet light irradiation 504 is between 10 minutes and 30 minutes. After the perovskite layer 502 is irradiated with ultraviolet light, decomposition occurs at the surface of the perovskite layer 502 to form a thin film 506. The thin film 506 is generally a halide thin film BX₂, where B may be Pb, Sn, or Ge, and X may be Cl, Br, or I. In an embodiment, the thin film 506 is, for example, a lead iodide thin film. The thin film 506 formed on the perovskite layer 502 may serve as a protective layer of the perovskite layer 502 to prevent damage to the perovskite layer 502 in subsequent processes.

When the perovskite layer 502 is formed by using the method described in the third embodiment, the ultraviolet light irradiation 504 may be performed after the ultraviolet light irradiation used to form the perovskite layer 502 is stopped. Alternatively, after the perovskite layer 502 is formed, the parameters (e.g., a wavelength, a duration, etc.) of the ultraviolet light irradiation may be directly changed to perform the ultraviolet light irradiation 504.

Referring to FIG. 4 and FIG. 5C at the same time, in step 404, after the thin film 506 is formed on the perovskite layer 502, a sputtering process 508 may be performed to form an inorganic layer 510 on the perovskite layer 502. Specifically, since the thin film 506 has been formed on the perovskite layer 502, when the sputtering process 508 is performed, damage to the perovskite layer 502 can be avoided, and the inorganic layer 510 can be formed on the perovskite layer 502 through the sputtering process 508 in a simple and quick manner. The inorganic layer 510 is, for example, an inorganic hole transport layer in a solar cell, but the disclosure is not limited thereto. In addition, during the sputtering process 508, the thin film 506 is gradually consumed, so the thin film 506 may also be referred to as a sacrificial layer.

The solar cell of a comparative example (in which the perovskite layer was not irradiated with ultraviolet light to form a sacrificial layer, and a sputtering process was directly performed to form an inorganic hole transport layer) and the solar cell of an experimental example (in which the perovskite layer was irradiated with ultraviolet light for 15 minutes to form a sacrificial layer on the surface, and a sputtering process was performed to form an inorganic hole transport layer) were subsequently sequentially deposited with spiro-OMeTAD and Au electrodes to form solar cells. Then, a light irradiation test was performed under light irradiation conditions of AM1.5, 1000 W/m², and 25° C. After the test, in terms of efficiency, the efficiency (3%) of the solar cell of the experimental example is significantly higher than the efficiency (0.2%) of the solar cell of the comparative example. The reason is that, in the comparative example, during the electroplating process of the perovskite layer, the perovskite layer is destroyed by plasma such that the formed solar cell could hardly work. In contrast, in the experimental example, since the perovskite layer was irradiated with ultraviolet light to form the sacrificial layer on the surface, the perovskite layer is not damaged by plasma during the electroplating process.

Although the disclosure has been disclosed with the above embodiments, the embodiments are not intended to limit the disclosure. Any person with ordinary skill in the art may make modifications and adjustments without departing from the spirit and scope of the disclosure. Therefore, the protection scope of the disclosure shall be determined by the claims attached hereafter.

1. A method for forming a perovskite layer, comprising:
coating a perovskite precursor material on a substrate;
performing a heating treatment on the substrate; and
performing an infrared light irradiation on the perovskite precursor material.

2. The method for forming a perovskite layer according to claim 1, wherein the heating treatment is performed before the infrared light irradiation.

3. The method for forming a perovskite layer according to claim 1, wherein the heating treatment and the infrared light irradiation are performed at the same time.

4. The method for forming a perovskite layer according to claim 1, further comprising performing an ultraviolet light irradiation on the perovskite precursor material, wherein the ultraviolet light irradiation is performed during the heating treatment, and an end time of the infrared light irradiation is not later than an end time of the ultraviolet light irradiation.

5. The method for forming a perovskite layer according to claim 4, wherein the ultraviolet light irradiation uses ultraviolet light having a wavelength of 320 nm to 400 nm.

6. The method for forming a perovskite layer according to claim 5, wherein a duration of the ultraviolet light irradiation is not more than 600 seconds.

7. The method for forming a perovskite layer according to claim 1, wherein a temperature of the heating treatment is between 60° C. and 150° C.

8. The method for forming a perovskite layer according to claim 1, wherein a duration of the heating treatment is between 30 minutes and 1 hour.

9. The method for forming a perovskite layer according to claim 1, wherein the infrared light irradiation uses infrared light having a wavelength of 700 nm to 1400 nm.

10. The method for forming a perovskite layer according to claim 1, wherein a duration of the infrared light irradiation is between 20 seconds and 30 minutes.

11. The method for forming a perovskite layer according to claim 1, wherein a method for coating the perovskite precursor material comprises a blade coating method, slot-die coating, or spray coating.

12. A method for forming a structure comprising a perovskite layer, comprising:
forming a perovskite layer on a substrate; and
performing a first ultraviolet light irradiation on the perovskite layer to form a protective layer on the perovskite layer, wherein a material of the protective layer comprises a halide BX₂, where B is Pb, Sn, or Ge, and X is Cl, Br, or I.

13. The method for forming a structure comprising a perovskite layer according to claim 12, wherein the first ultraviolet light irradiation uses ultraviolet light having a wavelength of 320 nm to 400 nm.

14. The method for forming a structure comprising a perovskite layer according to claim 12, wherein a duration of the first ultraviolet light irradiation is between 10 minutes and 30 minutes.

15. The method for forming a structure comprising a perovskite layer according to claim 12, wherein a method for forming the perovskite layer comprises:
coating a perovskite precursor material on the substrate;
performing a heating treatment on the substrate; and
performing an infrared light irradiation on the perovskite precursor material.

16. The method for forming a structure comprising a perovskite layer according to claim 15, wherein the heating treatment is performed before the infrared light irradiation.

17. The method for forming a structure comprising a perovskite layer according to claim 15, wherein the heating treatment and the infrared light irradiation are performed at the same time.

18. The method for forming a structure comprising a perovskite layer according to claim 15, further comprising performing a second ultraviolet light irradiation on the perovskite precursor material, wherein the second ultraviolet light irradiation is performed during the heating treatment, and an end time of the infrared light irradiation is not later than an end time of the second ultraviolet light irradiation.

19. The method for forming a structure comprising a perovskite layer according to claim 12, wherein after the protective layer is formed, the method further comprises performing a sputtering process to form an inorganic layer on the perovskite layer.

20. The method for forming a structure comprising a perovskite layer according to claim 19, wherein the inorganic layer is a hole transport layer.
